(19) United States
(12) Patent Application Publication
(10) Pub. No.: US 2008/0298154 A1
(43) Pub. Date: Dec. 4, 2008

(54) Semiconductor memory device

(75) Inventor: Kenji Mae, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/153,994

(22) Filed: May 28, 2008

(30) Foreign Application Priority Data
May 30, 2007 (JP) P2007-143143

(51) Int. Cl. G11C 7/00

(52) U.S. Cl. 365/222

(57) ABSTRACT

A semiconductor memory device includes: a plurality of banks each of which includes a plurality of mats each having normal word lines and redundant word lines; a first refresh generating circuit that generates a first refresh start signal for performing a first refresh operation in response to input of a refresh command; and a second refresh generating circuit that generates a second refresh start signal for performing a second refresh operation in response to a refresh operation end signal indicating that the first refresh operation ends.

### BACKGROUND OF THE INVENTION

1. Field of the Invention

The present invention relates to a semiconductor memory device, and more particularly, to a semiconductor memory device having a redundancy function for repairing a defective memory cell.

Priority is claimed on Japanese Patent Application No. 2007-143143, filed May 30, 2007, the content of which is incorporated herein by reference.

2. Description of the Related Art

In the related art, with an increase in the memory capacity of semiconductor integrated circuits, a redundancy technique has been used in order to prevent the product yield of the semiconductor integrated circuits from being lowered due to defects in memory cells. The redundancy technique provides redundant memory cells and replaces defective memory cells with the redundant memory cells, thereby improving the product yield.

Further, a semiconductor memory device having a flexible redundancy function has been proposed in order to repair defective memory cells with a small number of redundant cells (for example, Japanese Unexamined Patent Application, First Publication No. H11-224498).

That is, the following memory cell repairing method has been provided in which, as shown in FIG. 2, a redundant memory cell is provided in each of a plurality of mats divided from a bank and the redundant memory cell provided in one mat can be used by another mat. In this way, it is possible to improve the product yield with a small number of redundant memory cells.

In FIG. 2, a bank is divided into 32 mats M0 to M31 corresponding to word addresses X8 to X13, and a predetermined number of redundant word lines, for example, two redundant word lines, are provided in each mat.

As shown in FIG. 7, when the memory capacity increases, the semiconductor memory device is divided into a plurality of memory cell banks (banks B0 to B3 in FIG. 7). FIG. 2 shows the structure of one of the memory cell banks.

Further, a redundancy circuit flexibly performs a process of replacing a word line (hereinafter, referred to as a defective word line) corresponding to a defective memory cell with a word line corresponding to a redundant memory cell (hereinafter, referred to as a redundant word line). Therefore, whenever the redundant word line provided in each of the mats M0 to M31 is unavailable in this order, the redundant word line provided in the next mat is sequentially used.

For example, when two redundant word lines are provided in each mat and there are five defective word lines in the mat M0, five redundant word lines provided in the mats M0 to M2 are used.

In this way, even when the mats have different numbers of defective word lines, it is possible to flexibly perform the replacement of the redundant word lines. As a result, the number of redundant word lines used is averaged, and thus it is possible to improve the product yield.

However, in the above-mentioned structure, in order to perform a flexible word line repair process, as show in FIG. 1, the defective word line of the mat M2 corresponding to the address X12=0 and the defective word line of the mat M18 corresponding to the address X12=1 are likely to be replaced with the same redundant word line of the mat M7.

In the structure that activates double word lines to perform the refresh operation, when the defective word line of the mat M2 and the defective word line of the mat M18 are replaced with the redundant word line of the mat M7, and the defective word lines of the mats M2 and M18 have the same word addresses X0 to X11, two word lines are activated in the same mat.

That is, even when the memory capacity of the semiconductor memory device is doubled, it is necessary to maintain the original refresh cycle. Therefore, when the memory capacity is doubled, the refresh period is doubled, and thus it is necessary to improve the capability of a memory cell to hold the charge stored therein.

Meanwhile, when the memory cells have the same capability to hold the charge stored therein, it is necessary to refresh two word lines for one refresh period by driving 2n word lines in response to n refresh commands.

Therefore, as shown in FIG. 6, in order to activate double word lines, an address counter generates the word line addresses with treating the addresses X12 and X13 as “don't care”.

That is, when the mat M0 and the mat M16, the mat M1 and the mat M17, . . . , the mat M15 and the mat M31 have the same word addresses X0 to X11 by the word addresses X8 to X11, the addresses of the mats are considered to be equal during the refresh operation, even though the mats have different word addresses X12 and 13.

Similarly, when a defective word line of the mat M23 is replaced with the redundant word line provided in the mat M7, two word lines are activated in one mat because there are the same word addresses as the word addresses X0 to X11 of the defective word line.

In the above-mentioned mat structure, sense amplifiers are provided for the bit lines of each mat, and the sense amplifier selected by a column address reads data and outputs the read data to an amplifier for reading through an I/O line.

Therefore, when two word lines are activated in one mat, data is read from two memory cells through one bit line. In this case, when the two memory cells store different data, data is destroyed.

As shown in FIG. 5, the mats corresponding to the addresses X12 treated as “don't care” are classified into a mat group ‘0’ and a mat group ‘1’, and the range of the mats that are available for repairing the defective word line is limited to the mat groups, thereby setting the limit of a redundancy area.

However, when the number of defective word lines in the mat group ‘0’ is small and in the mat group ‘1’ is large, the replacement range of a normal product is limited, and the product is not determined as normal while the product would be determined as normal if it has the structure shown in FIG. 1. As a result, redundancy efficiency is lowered, which makes it difficult to improve product yield.

### SUMMARY OF THE INVENTION

The invention has been made to solve the above problems, and an object of the invention is to provide a semiconductor memory device capable of preventing two word lines corresponding to the same bit line from being simultaneously activated, without limiting the replacement range of defective word lines, when activating the two word lines during the same period to perform a refresh operation.

A first aspect of the present invention is a semiconductor memory device performing a refresh operation, including: a first refresh generating circuit which generates a first refresh start signal for performing a first refresh operation in response to input of a refresh command; and a second refresh generating circuit which generates a second refresh start signal for performing a second refresh operation in response to a refresh operation end signal indicating that the first refresh operation ends.

The refresh operation end signal of the first aspect of the present invention preferably can be a pre-charge end signal indicating that the precharging of a bit line is completed after the first refresh operation.

The semiconductor memory device of the first aspect of the present invention preferably further includes a refresh counter which generates the addresses of word lines to be refreshed in response to input of the refresh command. Preferably, the refresh counter performs a counting process whenever the first refresh start signal and the second refresh start signal generated in response to the input of the refresh command are input, and generates two refresh addresses whenever the refresh command is input.

The refresh counter of the first aspect of the present invention preferably generates a first refresh address used for the first refresh operation in response to input of the first refresh start signal, and generates a second refresh address used for the second refresh operation in response to input of the second refresh start signal.

A second aspect of the present invention is a refresh method of a semiconductor memory device that performs a refresh operation, including the steps of: generating a first refresh start signal for performing a first refresh operation in response to input of a refresh command; and generating a second refresh start signal for performing a second refresh operation in response to a refresh operation end signal indicating that the first refresh operation ends.

A third aspect of the present invention is a semiconductor memory device performing a refresh operation, including: a first circuit which generates a first refresh operation start signal based on a refresh command signal; a second circuit which generates a second refresh operation start signal based on a refresh operation end signal indicating that the refresh operation ends, and a selector circuit which receives the first refresh operation start signal and the second refresh operation start signal and outputs a third refresh operation start signal corresponding to either the first refresh operation start signal or the second refresh operation start signal. The refresh operation is performed based on the third refresh operation start signal.

The selector circuit of the third aspect of the present invention preferably can be controlled based on the third refresh operation start signal.

The selector circuit of the third aspect of the present invention preferably can be restricted selecting the second refresh operation start signal after the third refresh operation start signal corresponding to the second refresh operation start signal is output, and the selector circuit may then be allowed to select the second refresh operation start signal after the third refresh operation start signal corresponding to the first refresh operation start signal is output.

As described above, according to the above-mentioned aspects of the invention, after one word line has been completely refreshed, the other word line is refreshed in the semiconductor memory device that includes a plurality of banks each of which includes a plurality of mats, each having normal word lines and redundant word lines as word lines, when a defect occurs in a normal word line of one mat, the defective word line is replaced with a redundant word line provided in another mat. In contrast, when a refresh process of driving two word lines in one bank in response to one refresh command to refresh double memory cells is performed, two word lines are likely to be refreshed in the same mat.

Therefore, according to the above-mentioned aspects of the invention, as described above, two word lines are not simultaneously driven in response to input of a refresh command, and data from two memory cells is not output to the same bit line. As a result, data from the memory cells is not destroyed, unlike the related art.

### BRIEF DESCRIPTION OF THE DRAWINGS

FIG. 1 is a block diagram illustrating an example of the structure of a semiconductor memory device according to an embodiment of the invention;

FIG. 2 is a conceptual diagram illustrating a word line repair process between mats of a bank in the semiconductor memory device according to the embodiment of the invention;

FIGS. 3A and 3B are diagrams illustrating an example of the structure of a refresh start signal generating circuit shown in FIG. 1;

FIG. 4 is a conceptual diagram illustrating the configuration of a word line address output from a refresh counter shown in FIG. 1;

FIG. 5 is a conceptual diagram illustrating a word line repair process between mats of a bank in a semiconductor memory device according to the related art;

FIG. 6 is a timing chart illustrating the correspondence between a refresh cycle and word line addresses according to the related art; and

FIG. 7 is a conceptual diagram illustrating the bank structure of a memory cell array of a semiconductor memory device.

### DETAILED DESCRIPTION OF THE INVENTION

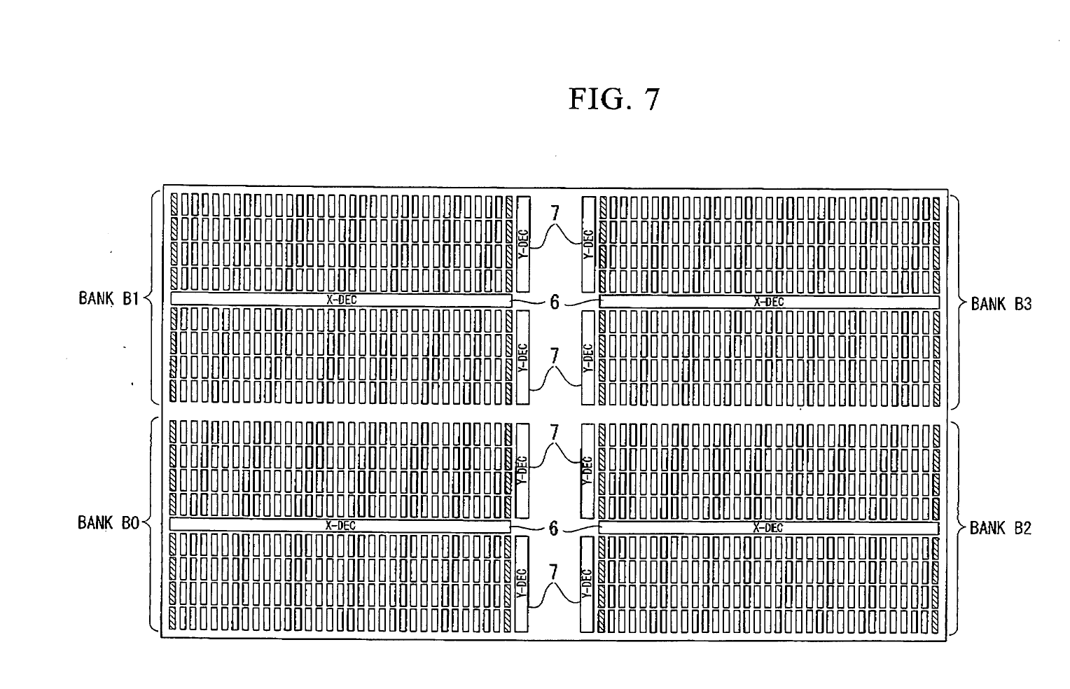

The invention is applied to a semiconductor device capable of improving a data holding function of memory cells of a memory cell array having a known bank structure shown in FIG. 7 by driving word lines (two word lines), which is twice the number of word lines according to the related art, in each bank during one refresh period in response to input of one refresh command, as in a conventional refresh process for semiconductor memory cells, such as DRAMs.

Further, the semiconductor memory device according to the invention includes a redundancy circuit that, when a defect is detected from a normal word line, replaces the defective normal word line with a redundant word line between the mats in the memory cell.

This refresh configuration makes it possible to prevent two word lines from being simultaneously driven in each bank including a plurality of mats in response to one refresh command (within one refresh period), unlike the related art. Specifically, one refresh period Tn is divided into two sub-periods Tn and Tn+1, and word lines Wn and Wn+1 are sequentially driven during the two sub-periods, thereby preventing two different word lines from being driven by the same bit line. That is, according to the invention, when a refresh command is input, the semiconductor memory device generates first and second refresh signals, and performs a refresh process on one word line during each of the two sub-periods.

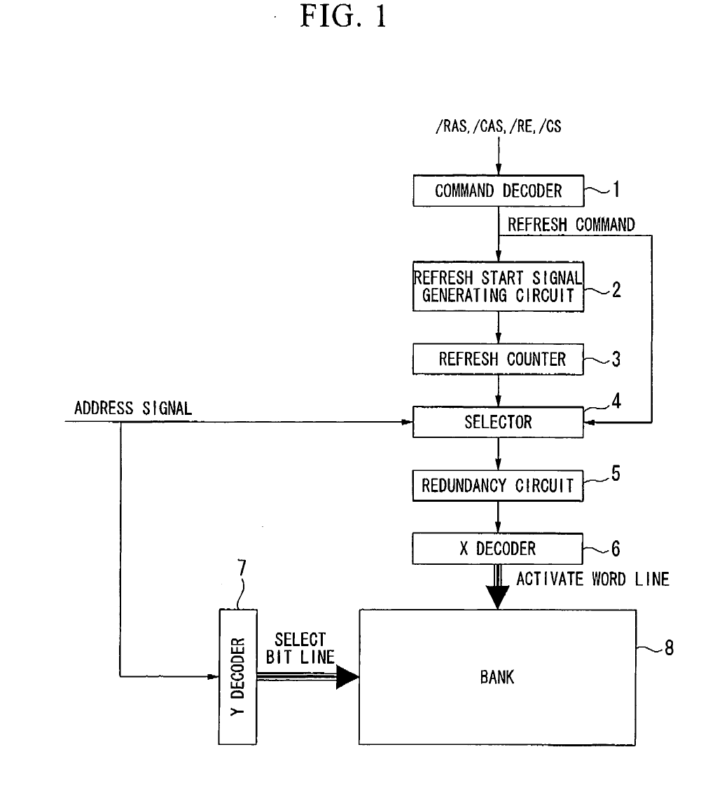

Hereinafter, a semiconductor memory device according to an embodiment of the invention will be described with reference to the accompanying drawings. FIG. 1 is a block diagram illustrating an example of the structure of the semiconductor memory device according to the embodiment.

In FIG. 1, the semiconductor memory device according to this embodiment of the invention has the same bank structure as that shown in FIG. 7, and includes a command decoder 1, a refresh start signal generating circuit 2, a refresh counter 3, a selector 4, redundancy circuits 5, X decoders 6, Y decoders 7, and a plurality of banks 8. The redundancy circuit 5, the X decoder 6, and the Y decoder 7 are provided for each bank.

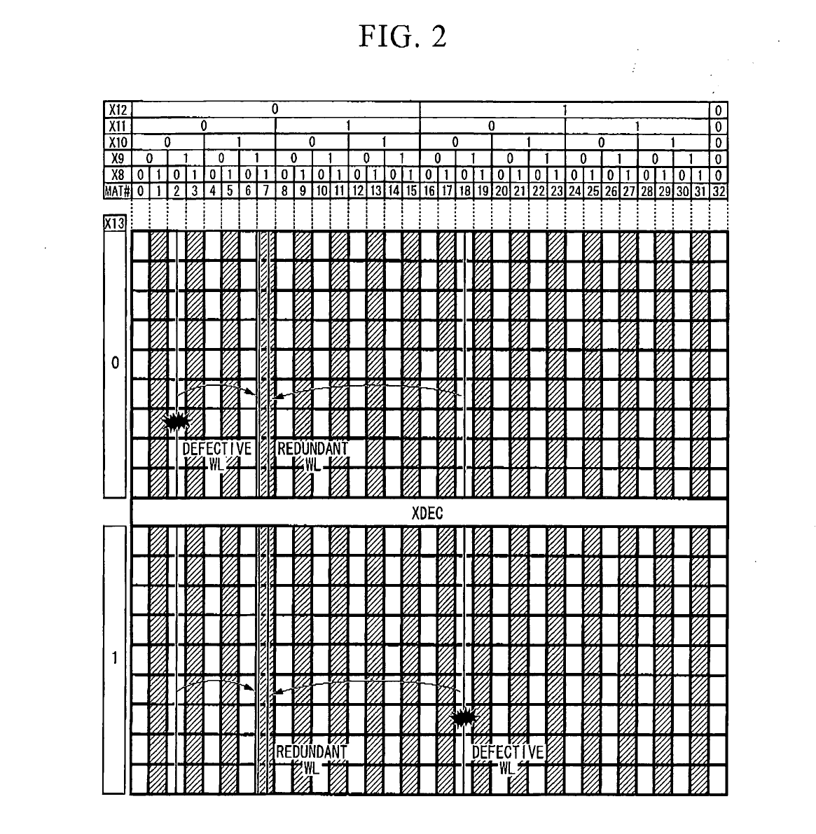

Each of the banks 8 is divided into a plurality of mats. For example, as shown in FIG. 2, the bank 8 is divided into 32 mats M0 to M31 that are set by word line addresses X8, X9, X10, X11, X12, and X13.

The mats M0 to M31 are formed by two redundant word lines and 256 normal word lines set by word line addresses X0 to X7, and a plurality of bit lines set by bit line addresses Y (Y0 to M).

The command decoder 1 generates internal control signals for controlling a refresh operation, a data read operation, and a data write operation for each of the banks 8 in response to control signals, such as /CAS (column address strobe), /RAS (row address strobe), /WE (write enable), and /CS (chip select). In the following description, the command decoder 1 generates and outputs refresh commands in response to the control signals. However, the operation of the command decoder 1 generating control signals for controlling the data write operation and the data read operation is not concerned with the invention, and thus a description thereof will be omitted.

When a refresh command is input, the refresh start signal generating circuit 2 generates a first refresh start signal and a second refresh start signal from the refresh command. The structure of the refresh start signal generating circuit 2 will be described in detail below.

The refresh counter 3 is a circuit that generates addresses for selecting word lines to be subjected to a refresh operation in response to input of the refresh command. The refresh counter 3 performs a counting operation in response to the first and second refresh start signals, and outputs word line addresses X0 to X12 (refresh addresses).

That is, the refresh counter 3 performs the counting operation whenever the first refresh start signal and the second refresh start signal generated in response to the input of the refresh command are input, and generates two refresh addresses whenever the refresh command is input.

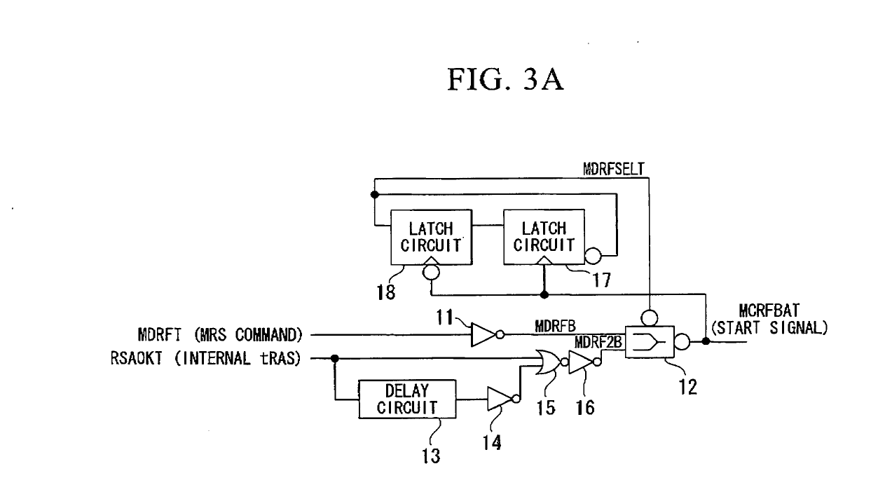

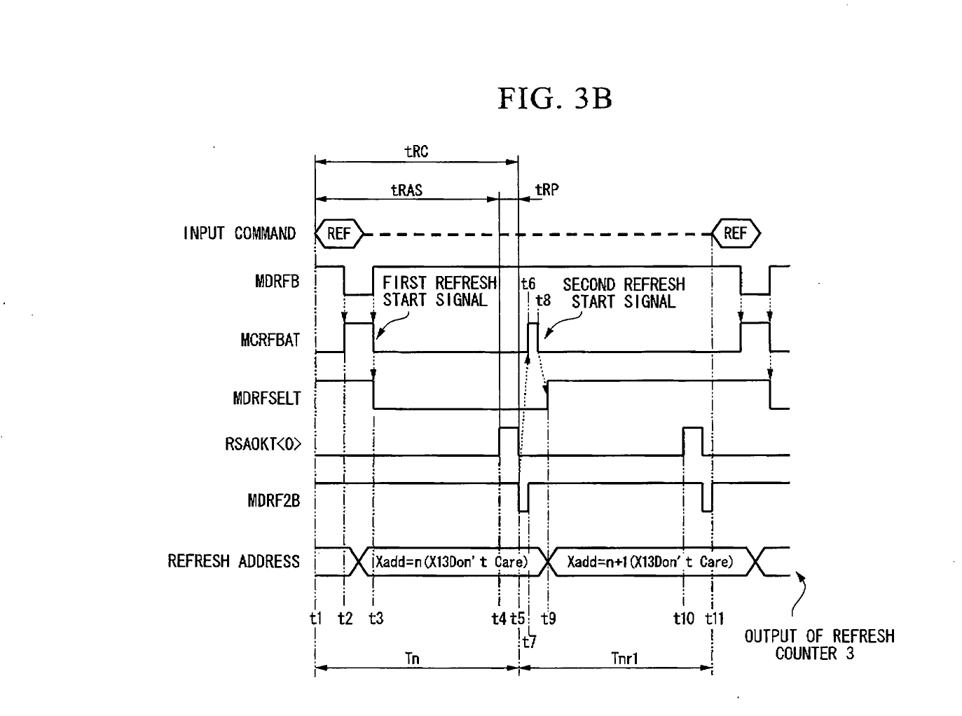

When the first refresh start signal is input, the refresh counter 3 generates a first refresh address that is used for the first refresh operation (the first half sub-period of the refresh period). When the second refresh start signal is input, the refresh counter 3 generates a second refresh address that is used for the second refresh operation (the second half sub-period of the refresh period). The first half sub-period corresponds to a period Tn shown in FIG, 3B, and the second half sub-period corresponds to a period Tn+1 shown in FIG. 3B.

During the refresh operation, since the most significant bit X13 of the word line address is treated as “don't care”, the word line address X13 is not used.

Even when the word line address X13 treated as “don't care”, in the bank structure shown in FIG. 2, two word lines are not selected by the same bit line in the same mat since the bit lines are divided from each other with the X decoder (XDEC in FIG. 2) 6 interposed therebetween.

The selector 4 selects whether to use the word line addresses X0 to X13 that are input from the outside or the word line addresses X0 to X12 that are output from the refresh counter 3, based on the refresh command.

When a defect occurs in a normal word line, the redundancy circuit S replaces the defective normal word line with a redundant word line provided in the mat. When the word line address indicating the redundant (replaced) word line is input, the redundancy circuit 5 outputs a replacement word line address for selecting the redundant word line to replace the defective word line to the X decoder 6.

The X decoder 6 selects word lines from the bank in response to the input word line addresses X0 to X13 or the replacement word line address. The replacement word line address is a word line address indicating the redundant word line provided in each mat.

The Y decoder 7 is a circuit that selects bit lines according to a bit line address Y other than the word line addresses X0 to X13 among the addresses input from the outside.

Next, the refresh start signal generating circuit 2 will be described with reference to FIGS. 3A and 3B. FIG. 3A is a block diagram illustrating an example of the structure of the refresh start signal generating circuit 2, and FIG. 3B is a timing chart illustrating the operation of the refresh start signal generating circuit 2.

In FIG. 3A, the refresh start signal generating circuit 2 includes, for example, inverters 11, 14, and 16, a selector 12, a delay circuit 13, a NOR circuit 15, and latch circuits 17 and 18.

The delay circuit 13, the NOR circuit 15, and the inverters 14 and 16 form a one-shot pulse circuit.

The operation of the refresh start signal generating circuit 2 will be described below with reference to FIG. 3B.

In FIG. 3B, a signal MDRFT is a refresh command output from the command decoder 1. At the timing when a signal RSAOKT changes from an ‘L’ level to an ‘H’ level, the refresh operation ends, and a sense amplifier for reading data can be used for the next process. At the timing when the signal RSAOKT changes from the ‘H’ level to the ‘L’ level, the bit line is completely pre-charged.

That is, a time tRAS (the time for which data is read and rewritten) has a period from the input of the refresh command to the rising of the signal RSAOKT. The pulse width of the signal RSAOKT is tRP (time required to pre-charge the bit line). Both the times tRAS and tRP are required for a control circuit to perform corresponding processes, and are obtained by delaying the refresh command using a delay circuit (not shown).

At the time when the signal /CS is input, the latch circuits 17 and 18 are reset, and ‘H’-level signals are output from an output terminal O17 (control signal MDRFSELT) and an output terminal O18. In this case, since the control signal MDRFSELT, which is a selection signal, is at the ‘H’ level, the selector 12 selects the control signal MDRFB of the control signal MDRFB and a control signal MDRF2B and outputs the selected signal.

At a time t1, when the command decoder 1 is instructed to perform a refresh operation by a combination of the control signals input from the outside, such as /CAS, /RAS, /WE, and /CS, the command decoder 1 generates a refresh command MDRFB in correspondence with the combination of the control signals.

At a time t2, when an ‘H’-level refresh command MDRFT is input, the inverter 11 inverts the received pulse and outputs a refresh pulse MCRFB at an ‘L’ level.

Then, the selector 12 inverts the control signal MDRFB, and outputs a start signal MCRFBAT as a first refresh signal at an ‘H’ level.

The latch circuit 17 holds ‘L’-level (an inverted signal of the ‘H’-level signal input from the latch circuit 18) data at the rising edge of the start signal MCRFBAT, and outputs the data from the output terminal O17.

At this time, since the latch circuit 18 reads data at the falling edge, the latch circuit 18 outputs the ‘H’-level signal without any change.

At a time t3, the command decoder 1 changes the level of the refresh command MDRF from an ‘H’ level to an ‘L’ level.

Therefore, the level of the start signal MCRFBAT output from the selector 12 also changes from an ‘H’ level to an ‘L’ level.

Then, the latch circuit 18 reads the ‘L’-level data input from the latch circuit 17 at the falling edge of the start signal MCRFBAT, and changes the level of the signal output from the output terminal O18, that is, the level of the control signal MDRFSELT from an ‘H’ level to an ‘L’ level.

Then, since the control signal MDRFSELT, which is a selection signal, is at the ‘L’ level, the selector 12 selects the control signal MDRF2B of the input control signals MDRFB and MDRF2B, and outputs the selected signal.

At this time, since the latch circuit 17 reads data at the rising edge, the latch circuit 17 outputs the ‘L’-level signal without any change.

At a time t4, the control circuit outputs the control signal RSAOKT indicating that the refresh process has been completed (the sense amplifier has been opened) by the first refresh start signal as an ‘H’ level pulse.

Then, the control circuit starts to pre-charge the bit line at the time when the control signal RSAOKT changes to an ‘H’ level.

At a time t5, the control circuit changes the level of the control signal RSAOKT to an ‘L’ level (pre-charge end signal) in order to indicate that the pre-charge operation has been completed. The time tRP is required to pre-charge the bit line. The period from the time t1 to the time t5 corresponds to the sub-period Tn of the refresh period.

The one-shot pulse circuit outputs the control signal MDRF2B as an ‘L’-level one-shot pulse in synchronization with the rising of the control signal RSAOKT.

The one-shot pulse changes to an ‘L’ level at the time t5, and changes to an ‘H’ level at a time t7. Therefore, the pulse width of the one-shot pulse is the time for which the one-shot pulse is maintained at the ‘L’ level.

At a time t6, the selector 12 inverts the control signal MDRF2B into an ‘H’-level pulse, and outputs the start signal MCRFBAT as the second refresh start signal.

In this case, the latch circuit 17 holds ‘H’-level (an inverted signal of the ‘L’-level signal input from the latch circuit 18) data at the rising edge of the start signal MCRFBAT, and outputs the data from the output terminal O17.

At this time, since the latch circuit 18 reads data at the falling edge, the latch circuit 18 outputs the ‘L’-level signal without any change.

At a time t8, since the control signal MDRF2B changes from the ‘L’ level to the ‘H’ level at the time t7, the selector 12 changes the level of the start signal MCRFBAT from the ‘H’ level to the ‘L’ level.

At a time t9, the latch circuit 18 reads the ‘H’-level data input from the latch circuit 17 at the falling edge of the start signal MCRFBAT, and changes the level of the signal output from the output terminal O18, that is, the level of the control signal MDRFSELT from an ‘L’ level to an ‘H’ level.

Then, since the control signal MDRFSELT, which is the selection signal, is at the ‘H’ level, the selector 12 selects the control signal MDRFB of the input control signals MDRFB and MDRF2B, and outputs the selected signal.

At this time, since the latch circuit 17 reads data at the rising edge, the latch circuit 17 outputs the ‘H’-level signal without any change.

At a time t10, the control circuit outputs the control signal RSAOKT indicating that the refresh process has been completed by the second refresh start signal as an ‘H’-level pulse.

Then, the control circuit starts to pre-charge the bit line at the time when the control signal RSAOKT changes to the ‘H’ level.

At a time t11, the control circuit changes the level of the control signal RSAOKT to an ‘L’ level in order to indicate that the pre-charge operation has been completed. The period from the time t5 to the time t11 corresponds to the sub-period Tn+1 of the refresh period.

In this embodiment, the one-shot circuit outputs the pulse of the control signal MDRF2B. However, since the control signal MDRFSELT, serving as the selection signal, is at the ‘H’ level, the selector 12 selects the control signal MDRFB of the input control signals MDRFB and MDRF2B, and outputs the selected signal. Therefore, at this time, the selector 12 does not output the start signal MCRFBAT.

As described above, whenever the refresh command MDRFT is input, the process from the time t1 to the time t11 is repeated. The refresh start signal MCRFBAT is output during each of the sub-periods Tn and Tn+1 of one refresh period.

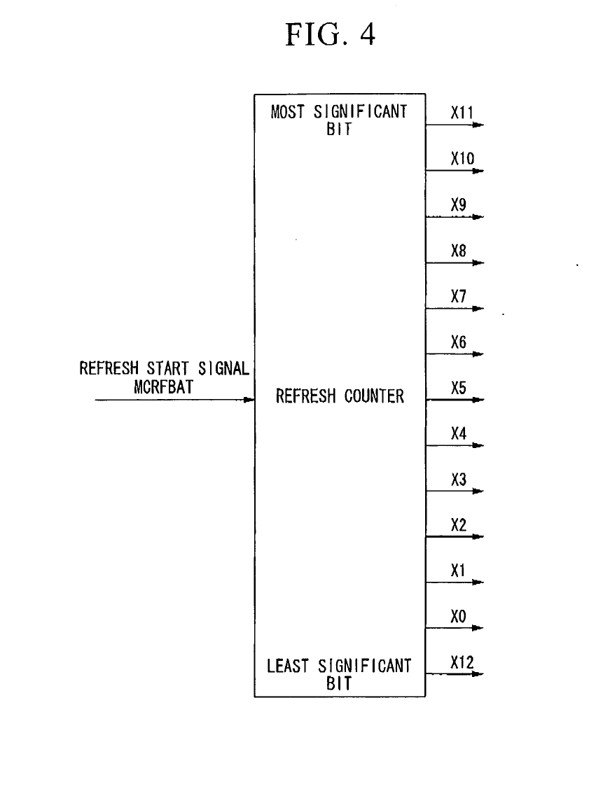

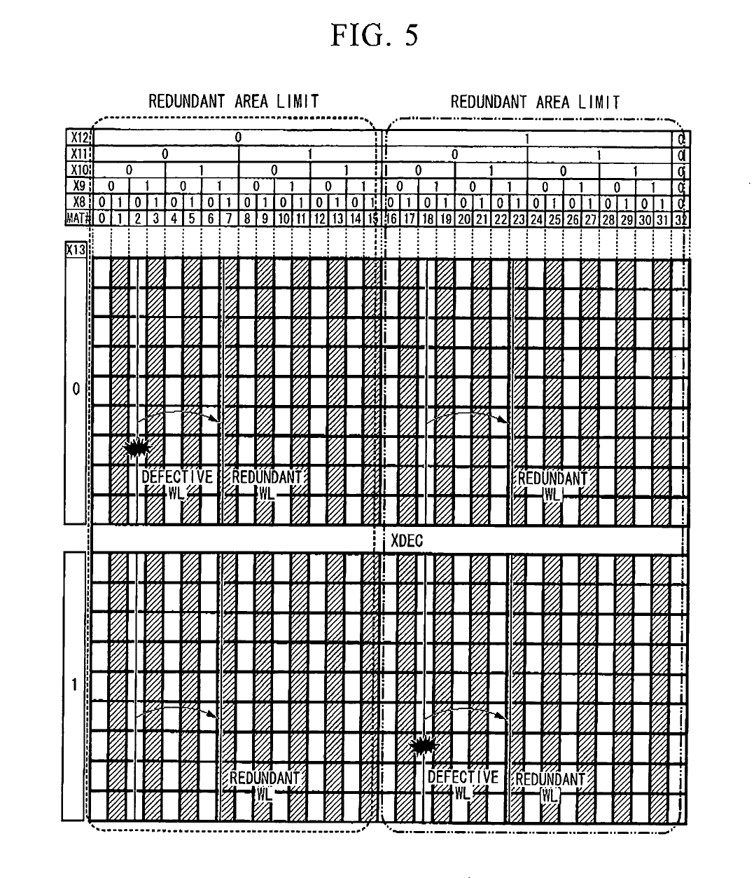

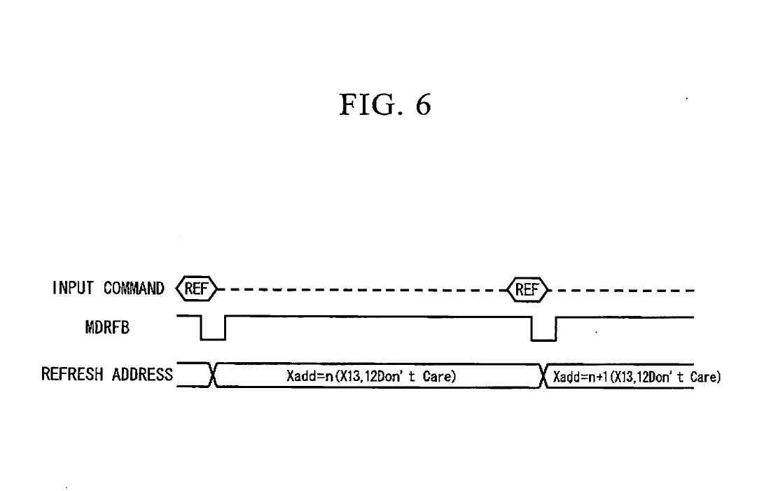

Next, the structure of the refresh counter 3 will be described with reference to FIG. 4. FIG. 4 is a conceptual diagram illustrating an example of the word line address output from the refresh counter 3.

When the control signal MCRFBAT, that is, the first refresh start signal and the second refresh start signal are input, the refresh counter 3 performs a counting operation and outputs the word line addresses X0 to X12.

Among the numerical values output from the refresh counter, the most significant bit is X11, followed by X10, X9, X8, X7, X6, X5, X4, X3, X2, X1, and X0 in this order, and the least significant bit is X12.

As such, in the structure that drives double word lines for an external refresh period, the refresh counter 3 according to this embodiment generates the word line address X12, which is generally treated as “don't care”, as the least significant address bit, for example.

In this way, as shown in FIG. 3B, during the sub-period Tn started by the first refresh start signal, the word lines corresponding to the word line addresses X0 to X11=n, and the word line address X12=0 are driven to perform the refresh process. During the sub-period Tn+1 started by the second refresh start signal, the word lines corresponding to the word line addresses X0 to X11=n and the word line address X12=1 are driven to perform the refresh process.

In the structure that drives double word lines for one refresh period, among the word line addresses that are generally treated as “don't care”, the word line address that is used to divide the refresh period into two sub-periods uses the most significant address bit of the word line addresses forming a mat.

In this embodiment, the word line address X12 has the least significant bit, but it is necessary to perform the above-mentioned setting process according to a circuit structure.

In this embodiment, the bit lines are divided from each other by the X decoder (XDEC) 6. Therefore, as described above, even when the word line address X13 is treated as “don't care”, two word lines are not driven by one bit line.

As described above, the refresh period started by the refresh command is divided into two sub-periods Tn and Tn+1, and one word line is refreshed during each of the two sub-periods. Therefore, different word lines are not driven by the same bit line.

For example, as shown in FIG. 2, even when defects occur in the word lines of the mats M2 and M18 and the word lines are both replaced with a redundant word line of the mat M7, the word line replacing that of the mat M2 is driven during the sub-period Tn and the word line replacing that of the mat M18 is driven during the sub-period Tn+1 by the same bit line of the mat M7.

Therefore, unlike the related art, two different word lines are not simultaneously driven by the same bit line, and thus data stored in each memory cell is not damaged.

In addition, the second refresh start signal is generated by the control signal indicating that the bit line has been completely pre-charged, which enables the next refresh operation after the sub-period Tn started by the first refresh start signal is completed.

Therefore, according to this embodiment, even when the word lines connected to the same bit line are continuously refreshed during the same refresh period, the precharging of the bit line is completed before the sub-period Tn+1 starts. As a result, it is possible to sequentially and continuously perform the refresh process on two word lines during one refresh period.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor memory device performing a refresh operation, comprising:
a first refresh generating circuit which generates a first refresh start signal for performing a first refresh operation in response to input of a refresh command; and
a second refresh generating circuit which generates a second refresh start signal for performing a second refresh operation in response to a refresh operation end signal indicating that the first refresh operation ends.

2. The semiconductor memory device according to claim 1, wherein the refresh operation end signal is a pre-charge end signal indicating that the precharging of a bit line is completed after the first refresh operation.

3. The semiconductor memory device according to claim 1, further comprising:
a refresh counter which generates the addresses of word lines to be refreshed in response to input of the refresh command,
wherein the refresh counter performs a counting process whenever the first refresh start signal and the second refresh start signal generated in response to the input of the refresh command are input, and generates two refresh addresses whenever the refresh command is input.

4. The semiconductor memory device according to claim 3, wherein the refresh counter generates a first refresh address used for the first refresh operation in response to input of the first refresh start signal, and generates a second refresh address used for the second refresh operation in response to input of the second refresh start signal.

5. A refresh method of a semiconductor memory device that performs a refresh operation, comprising the steps of:
generating a first refresh start signal for performing a first refresh operation in response to input of a refresh command; and
generating a second refresh start signal for performing a second refresh operation in response to a refresh operation end signal indicating that the first refresh operation ends.

6. A semiconductor memory device performing a refresh operation, comprising:
a first circuit which generates a first refresh operation start signal based on a refresh command signal;
a second circuit which generates a second refresh operation start signal based on a refresh operation end signal indicating that the refresh operation ends; and
a selector circuit which receives the first refresh operation start signal and the second refresh operation start signal, and outputs a third refresh operation start signal corresponding to either the first refresh operation start signal or the second refresh operation start signal,
wherein the refresh operation is performed based on the third refresh operation start signal.

7. The semiconductor memory device according to claim 6,
wherein the selector circuit is controlled based on the third refresh operation start signal.

8. The semiconductor memory device according to claim 7, wherein:
the selector circuit is restricted selecting the second refresh operation start signal after the third refresh operation start signal corresponding to the second refresh operation start signal is output; and
the selector circuit is allowed to select the second refresh operation start signal after the third refresh operation start signal corresponding to the first refresh operation start signal is output.
